(19) United States
(12) Patent Application Publication
(10) Pub. No.: US 2023/0005824 A1
(43) Pub. Date: Jan. 5, 2023

(54) METHOD OF MANUFACTURING SUBSTRATES FOR SEMICONDUCTOR DEVICES, CORRESPONDING SUBSTRATE AND SEMICONDUCTOR DEVICE

(71) Applicant: STMicroelectronics S.r.l., Agrate Brianza (MB) (IT)

(72) Inventor: Mauro MAZZOLA, Calvenzano (BERGAMO) (IT)

(73) Assignee: STMicroelectronics S.r.l., Agrate Brianza (MB) (IT)

(21) Appl. No.: 17/848,612

(22) Filed: Jun. 24, 2022

(30) Foreign Application Priority Data
Jun. 30, 2021 (IT) 102021000017231

(51) Int. Cl. H01L 23/495; H01L 21/48

(52) U.S. Cl. CPC H01L 23/49541; H01L 23/49503; H01L 21/4821

(57) ABSTRACT

Pre-molded leadframes for semiconductor devices are manufactured by molding electrically insulating material onto a laminar sculptured structure of electrically conductive material including semiconductor device component die pads. First and second die pads are coupled via a first extension from the first die pad and a second extension from the second die pad at neighboring locations on the front surface of the leadframe and a bridge formation coupling the first and second extensions at the bacpk surface of the leadframe. The bridge formation provides a sacrificial connection between the first and second extensions which is selectively removed after molding the electrically insulating material in order to decouple the first and second die pads from each other. The removal of the sacrificial connection leaves a cavity formed at the second surface of the leadframe without affecting the shape of the die pads.

### PRIORITY CLAIM

This application claims the priority benefit of Italian Application for Patent No. 102021000017231, filed on Jun. 30, 2021, the content of which is hereby incorporated by reference in its entirety to the maximum extent allowable by law.

### TECHNICAL FIELD

The description relates to manufacturing semiconductor devices.

One or more embodiments may apply to manufacturing pre-molded leadframes for semiconductor devices.

### BACKGROUND

Semiconductor devices may comprise one or more semiconductor integrated circuit chips or dice arranged (attached) on a substrate such as a leadframe.

Plastic packages are commonly used for semiconductor devices. Such packages may include a leadframe providing a base substrate comprising electrically conductive material such as copper, sized and shaped to accommodate semiconductor chips or dice and providing pad connections (leads) for these chips or dice.

The designation “leadframe” (or “lead frame”) is currently used (see, for instance the USPC Consolidated Glossary of the United States Patent and Trademark Office) to indicate a metal frame that provides support for an integrated circuit chip or die as well as electrical leads to interconnect the integrated circuit in the die or chip to other electrical components or contacts.

Leadframes are conventionally created using technologies such as a photo-etching technology. With this technology, metal (e.g., copper) material in the form of a foil or tape is etched on the top and bottom sides to create various pads and leads.

So-called “pre-molded” leadframes include electrically insulating resin such as epoxy resin, for instance, molded onto a sculptured (e.g., photo-etched) metal leadframe structure using a flat molding tool, for instance.

Spaces left in the etched metal material are filled by pre-mold resin and the resulting leadframe has a total thickness which is the same thickness of the original etched leadframe.

After pre-molding (with the molded resin solidified, via heat or UV curing, for instance), de-flashing and smearing processes can be applied to provide clean top/bottom metal surfaces of the leadframe.

Such pre-molded leadframes are used in a wide variety of semiconductor devices.

Certain pre-molded leadframes (for instance, for use in power semiconductor devices packaged in Quad-Flat No-leads (QFN) packages) may include plural die pads for arranging semiconductor chips or dies and associated components.

These die pads are intended to be finally isolated from one another. However, connecting bars are useful in mechanically coupling these pads either to a metal (e.g., copper) frame in the leadframe and/or to other die pads in the leadframe while the pre-mold resin is molded onto the sculptured metal structure of the leadframe.

These connecting bars are useful in avoiding negative phenomena such as undesired displacement of the die pads or “flashing” of the pre-mold resin over the metal surfaces of the leadframe.

The connecting bars are then removed, for instance during a subsequent (half) etching process applied to the pre-molded leadframe to form wettable flanks for soldering.

This processing may however leave certain defects that are difficult to control in production and may result in part rejection or quality issues at the customer board level.

There is a need in the art to contribute to avoiding the drawbacks outlined in the foregoing.

### SUMMARY

One of more embodiments relate to a method.

One of more embodiments relate to a corresponding (pre-molded) leadframe.

One of more embodiments relate to a corresponding semiconductor device. A Quad-Flat No-leads (QFN) power device may be exemplary of such a device.

One or more embodiments propose a design for the metal (e.g., copper) bottom side and top side of a leadframe which provides temporary (sacrificial) connection bars that can be removed without negatively affecting the die pad outline on the back side or bottom side of the device package, for instance.

One or more embodiments do not involve additional process steps over conventional pre-molded leadframe manufacturing.

One or more embodiments may provide a multi-die pad pre-molded leadframe including die pad connection bars with a bridge-like portion at the back (or bottom) side of the leadframe. Such a bridge-like portion is arranged remote from the die pads connected thereby and can be removed during subsequent processing (such as a second half-etching step after molding) without adverse effects on the outline of the die pads.

One or more embodiments effectively reduce part rejection due to die pad defects. Visual inspection of a semiconductor device (a power QFN package, for instance) comprising a pre-molded leadframe according to embodiments will thus identify die pads (of the low-voltage die, for instance) with a regular (virtually perfect) rectangular outline with a recessed portion (cavity) in the molding exposing two sides of the bridge “opened” as a result of a connecting bar being removed.

### BRIEF DESCRIPTION OF THE DRAWINGS

One or more embodiments will now be described, by way of example only, with reference to the annexed figures, wherein:

FIGS. 1A and 1B are plan views of a pre-molded leadframe;

FIG. 1C shows the views of FIGS. 1A and 1B mutually superposed;

FIG. 2 is a view of the portion of FIG. 1C indicated by arrow II reproduced on an enlarged scale;

FIG. 3 is a cross-sectional view along line of FIG. 2;

FIG. 4 is a view of a pre-molded leadframe substantially corresponding to FIG. 1C, after removal of a connection element as discussed herein;

FIG. 5 is a view of the portion of FIG. 4 indicated by arrow V reproduced on an enlarged scale; and

FIG. 6 is a cross-sectional view along line VI-VI in FIG. 5.

### DETAILED DESCRIPTION

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

In the ensuing description, various specific details are illustrated in order to provide an in-depth understanding of various examples of embodiments according to the description. The embodiments may be obtained without one or more of the specific details, or with other methods, components, materials, etc. In other cases, known structures, materials, or operations are not illustrated or described in detail so that various aspects of the embodiments will not be obscured.

Reference to “an embodiment” or “one embodiment” in the structure of the present description is intended to indicate that a particular configuration, structure, or characteristic described in relation to the embodiment is comprised in at least one embodiment. Hence, phrases such as “in an embodiment”, “in one embodiment”, or the like, that may be present in various points of the present description do not necessarily refer exactly to one and the same embodiment. Furthermore, particular configurations, structures, or characteristics may be combined in any adequate way in one or more embodiments.

The headings/references used herein are provided merely for convenience and hence do not define the extent of protection or the scope of the embodiments.

Semiconductor devices such as, for instance, power devices, comprise a substrate (leadframe) onto which semiconductor chips or dice and other electrical components are mounted with solder glue or other processes, with wires and/or “ribbons” providing electrical connection to the semiconductor chips.

An encapsulation of molding resin (an epoxy resin, for instance) incorporates these elements in a (plastic) main body of the semiconductor device.

A substrate or leadframe 12 is produced starting from a foil or strip of metal material (copper) for instance, onto which a “sculptured” conformation is bestowed by photoetching technology, for instance.

In pre-molded leadframes a pre-mold resin is molded onto the sculptured metal structure of the leadframe to fill the spaces left free therein. The resulting “pre-molded” leadframe has the same thickness of the original metal material sheet or foil.

Further processing (for instance a second etching step) can be applied to the pre-mold leadframe to remove additional copper for various reasons such as, for instance, to provide wettable flanks of the leadframe for soldering or connecting bars.

Pre-molded leadframes may include two or more die pads (that is areas onto which semiconductor chips and/or other components are intended to be attached) and may exhibit a complex design.

This makes connection to outer bars in the leadframe difficult, especially if pad number maximization is pursued.

Stability, that is avoiding undesired deformation/displacement during pre-molding, and saving space for additional pads are factors suggesting that temporary (sacrificial) connection bars are formed between adjacent die pads at the bottom or back side of the sculptured metal structure of the leadframe.

These bars are finally removed, e.g., via a chemical reaction during a second etching step, so that the die pads are finally isolated (mechanically and electrically) from one another.

This processing can be detected by visual inspection of the back or bottom side of the pre-molded leadframe, with void spaces (cavities) visible where metal (copper, for instance) was removed thus exposing the pre-mold resin.

Unless otherwise indicated, leadframe processing as discussed in the foregoing is conventional in the art, which makes it unnecessary to provide a more detailed description herein.

A problem encountered in performing operations as discussed in the foregoing is related to tolerances inherent in processes such as etching, which ultimately have an impact on the final shape (outline) of the die pads.

For instance, undesirably poor etching may result in metal material remaining that exceeds (that is, undesirably protrudes) from the desired rectangular shape of a die pad.

Alternatively, in the case of over-etching, metal material can be undesirably removed from the periphery of the die pad again resulting in an undesirably irregular rectangular die pad shape.

That is: undesired metal material may remain attached in the case of poor etching; and more material than desired may be removed in the case of over-etching.

In both cases, the shape of die pad will exhibit undesired uncontrolled protrusions or notches that are regarded as defects of the pre-molded leadframe.

These defects are visible at the die pad surfaces and deviations from a desired (e.g., substantially rectangular) shape may negatively affect package resistance and/or solder joint reliability.

Such drawbacks may be attempted to be palliated by controlling more accurately the parameters of the second etching process, for instance, and/or modifying the solder etching mask at the substrate (a printed circuit board or PCB, for instance) onto which the semiconductor product is mounted.

These solutions may undesirably add to the cost of manufacturing the leadframe and the corresponding semiconductor device without completely overcoming the drawbacks discussed in the foregoing.

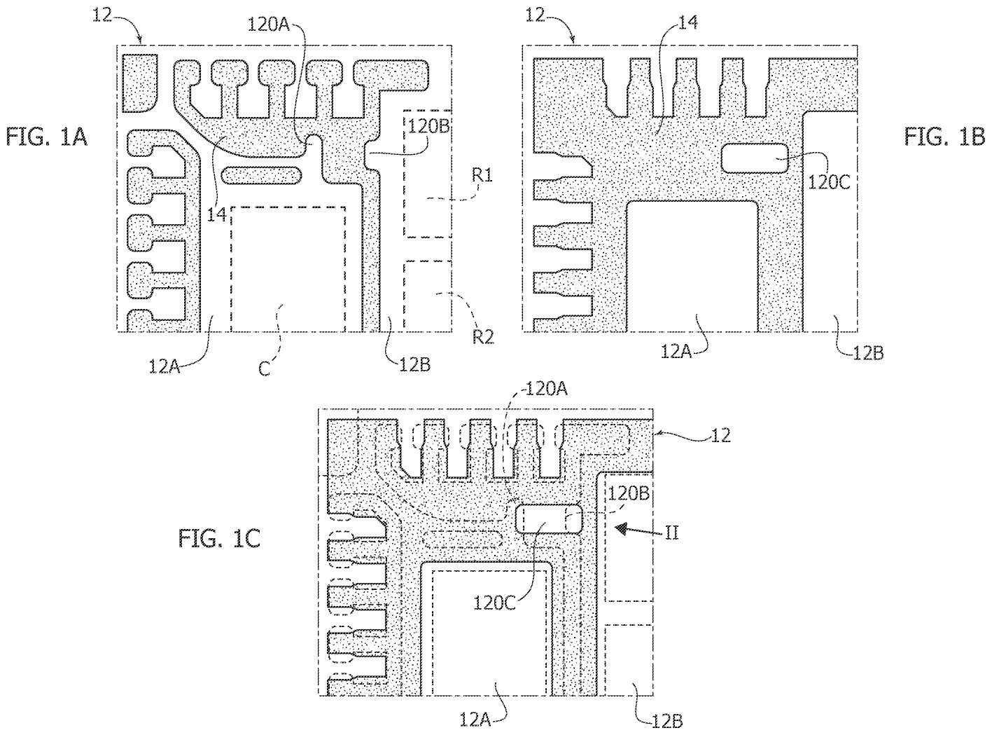

FIGS. 1A and 1B are plan views (at the level of the top or front side and at the level of the bottom or back side, respectively) of a portion of pre-molded leadframe 12.

As discussed previously (and as otherwise conventional in the art), the leadframe 12 comprises a sculptured metal (e.g., copper) structure—formed by etching a metal foil or strip—including a plurality of die pads onto which one or more semiconductor chips and associated components are intended to be mounted, via a die-attach material, for instance.

For the sake of simplicity and ease of explanation, the description and the figures refer to the presence of (only) two die pads, indicated 12A and 12B, respectively. As noted, one or more embodiments can be advantageously applied to leadframes comprising a higher number (three or more) of die pads.

As illustrated only in FIG. 1A, the die pads 12A and 12B are intended to host attached thereon semiconductor chips or dice or, possibly, components such as “ribbons” this being particularly the case of a power device.

Those of skill in art will otherwise appreciate that embodiments are discussed herein are largely “transparent” to the nature and configuration of the components such as C, R1, R2 intended to be mounted onto the die pads such as 12A, 12B.

In the examples described herein, the two die pads 12A and 12B are assumed to be (temporarily) connected via one (or, advantageously, plural) sacrificial connection bars while pre-mold resin 14 is molded onto the metal structure of the leadframe 12 to provide a pre-molded leadframe as otherwise conventional in the art.

The sacrificial connection bars are then at least partially removed so that the two die pads 12A and 12B are finally isolated.

The examples illustrated refer for simplicity and ease of explanation to one such connecting bar comprising: respective extensions 120A, 120B of the (electrically conductive) die pads 12A, 12B, at one of the surfaces (the front or top surface, for instance) of the leadframe 12, and an (electrically conductive) bridge element 120C coupling the extensions 120A, 120B, the bridge element 120C being provided on the opposed surface (here the back or bottom surface, for instance) of the leadframe 12.

The element 120C extends bridge-like between the extensions 120A, 120B being de facto one-piece therewith thus providing (temporary) mechanical and electrical connection between the die pads 12A, 12B.

Again, while a single set of two extensions 120A, 120B from the die pads 13A, 12B and a connecting element 120C extending bridge-like therebetween is illustrated here for simplicity, a plurality of such sets can be provided in the leadframe 12 at locations where plural die pads such as 12A, 12B are desired to be (temporarily) connected during pre-molding.

The spatial relationship between the extensions 120A, 120B (on one side of the leadframe) and the bridge element 120C (on the other side of the leadframe) is further exemplified in FIG. 1C.

FIG. 1C essentially reproduces the plan view of the leadframe 12 at the level of the back or bottom surface as illustrated in FIG. 1B with the layout of the metal parts of the leadframe 12 at the front or top surface of the leadframe 12 reproduced in dashed lines.

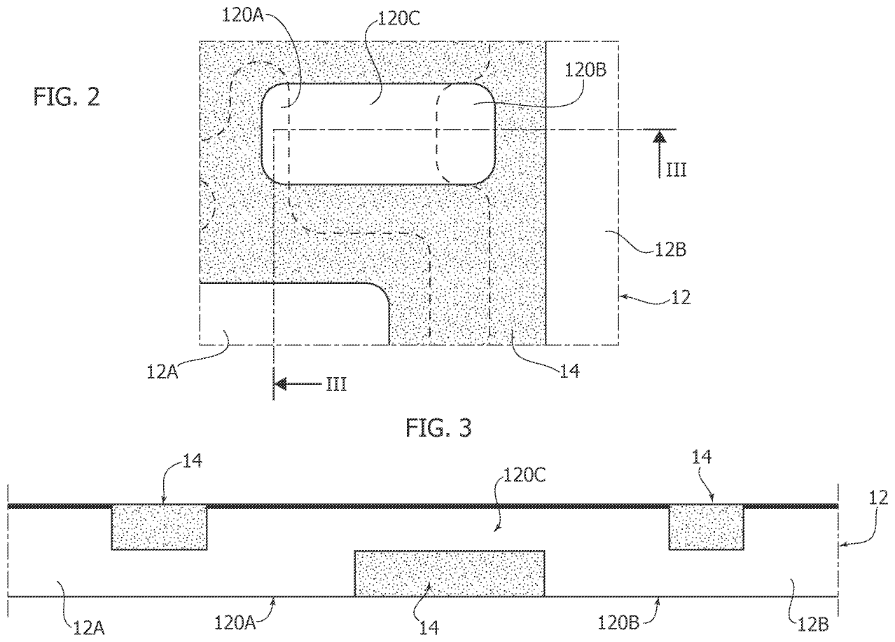

This spatial relationship is further exemplified in the enlarged view of FIG. 2 with the cross-sectional view of FIG. 3 further detailing the relative positions of extensions 120A, 120B and the bridge 120C therebetween.

It will be appreciated that: the cross-sectional view of FIG. 3 is taken along line III-III FIG. 2, such a line having a 90° bend at the extension 120A (with an end portion of the bridge element 120C located in a corresponding position on the opposite side of the leadframe 12); and in the cross-sectional view of FIG. 3 the bottom or back surface of the leadframe 12 faces upwards while the top or front surface faces downwards.

Also, while preserving the connection therebetween, both extensions 120A and 120B, as well as the bridge-like element 120C can be shaped and sized with a certain degree of freedom.

Advantageously, the extensions 120A, 120B are formed at neighboring locations so that the distal ends of these extensions are located at a short distance therebetween.

A rectilinear or substantially rectilinear (quadrangular) shape was found to be advantageous for the extensions 120A, 120B.

Similarly, a linear (e.g., rectangular) shape with rounded edges was found to be advantageous for the bridge-like connecting element 120C.

The cross-sectional view of FIG. 3 illustrates the possibility for the pre-molding encapsulation material 14 to penetrate into the sculptured metal (e.g., copper) structure of the leadframe 12 filling the empty spaces therein.

FIGS. 1A to 1C, 2, and 3 are thus exemplary of molding electrically insulating material 14 onto a laminar sculptured structure of electrically conductive material to produce a leadframe 12 comprising a plurality of die pads 12A, 12B configured to have semiconductor device components C, R1, R2 mounted thereon.

The leadframe 12 has opposed first and second surfaces and one (or more) pairs of die pads 12A, 12B. As illustrated these die pads 12A, 12B are coupled via (at least one) sacrificial coupling formation intended to be at least partly removed; this is after this or these sacrificial coupling formations have assisted in countering undesired displacement of the die pads while electrically insulating material (that is, the pre-mold resin 14) is molded onto the laminar sculptured structure of electrically conductive material of the leadframe 12.

In that way, the die pads 12A, 12B can be finally decoupled as desired.

As illustrated, a first extension 120A of the first die pad 12A and a second extension 120B of the second die pad 12B are provided at a first surface (e.g., the front or top surface) of the laminar sculptured structure of electrically conductive material, for instance during manufacturing that metal (e.g., copper) structure as otherwise conventional in the art (e.g., via photoetching).

As illustrated, the extensions 120A and 120B are provided (formed) at neighboring locations of the first surface of the leadframe 12.

As illustrated, an (electrically conductive) formation 120C is provided at the second surface (e.g., the back or bottom surface) of the laminar sculptured structure of the leadframe 12. Again, this may occur during manufacturing that metal (e.g., copper) structure as otherwise conventional in the art.

As visible in FIG. 3, for instance, the formation 120C extends bridge-like between the first extension 120A and the second extension 120B thus providing a sacrificial coupling formation (connecting bar) of the die pads 12A, 12B.

As illustrated, the first extension 120A and the second extension 120B are advantageously provided as finger-like extensions and/or advantageously have distal ends located at a distance from the die pads 12A, 12B with the element or formation 120C extending bridge-like between these distal ends.

As a result, the formation 120C ends up by being located at a distance from the die pads 12A, 12B.

Advantageously, the first extension 120A and the second extension 120B are provided as mutually converging extensions from the die pads 12A, 12B.

As discussed, the sacrificial coupling formation(s) such as 120A, 120B, 120C are at least partly removed to isolate the die pads 12A, 12B after molding (and solidifying, via heat or UV curing for instance) the insulating pre-mold material 14 which penetrates (see FIG. 3, for instance) into the empty spaces in the laminar sculptured metal structure of the leadframe 12.

Such an at least partial removal may involve at least partly removing (e.g., during a further etching step for forming solder wettable flanks, for instance) the formation 120C extending bridge-like between the first extension 120A and the second extension 120B.

Skipping for simplicity to FIG. 6, one may note that: as a result of the bridge formation 120C (whose outline is shown in a dashed line) being removed, the die pads 12A, 12B still exhibit, at neighboring locations of the front or top surface of the leadframe (pointing downwards in FIG. 6) a first extension 120A and a second extension 120B; and conversely, the back or bottom surface of the leadframe 12 has a recessed portion (cavity) 120C′ extending bridge-like (at the back or bottom surface of the leadframe 12) between the first extension 120A and the second extension 120B (these latter being provided at the front or top surface of the lead frame).

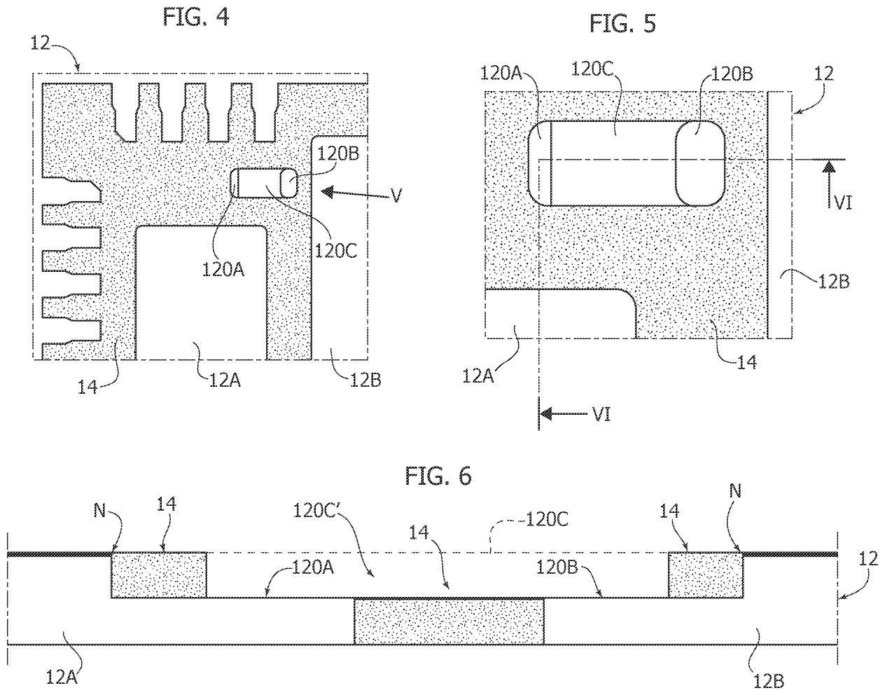

As exemplified in the views of FIGS. 4 and 5, removing the bridge formation or element 120C (via “secondary” etching, for instance) leaves in the cavity 120C′ very “clean” surfaces N towards the surrounding metal parts.

The die pads 12A, 12B are thus separated without creating undesired defects (protrusions due to poor etching or notches due to over-etching, for instance) in their outline.

As exemplified in the views of FIGS. 4 and 5, the bridge-like element 120C is thus removed without adversely affecting the profile of the die pads 12A, 12B. That is, no defects are produced on the exposed surfaces of the die pads 12A, 12B, as a result of the connection bar represented by the bridge element 120C being removed.

It will be appreciated that the die pad extensions 120A, 120B provided on the opposed (here front or top) surface are in no way affected by the removal of the bridge-like element (connecting bar) 120C.

Without prejudice to the underlying principles, the details and embodiments may vary, even significantly, with respect to what has been described in the foregoing, by way of example only, without departing from the extent of protection.

The claims are an integral part of the technical teaching provided herein in respect of the embodiments.

The extent of protection is determined by the annexed claims.

1. A method, comprising:
molding electrically insulating material onto a laminar sculptured structure of electrically conductive material to produce a leadframe having opposed first and second surfaces and comprising first and second die pads configured to have semiconductor device components mounted thereon;
providing in the laminar sculptured structure of electrically conductive material, at neighboring locations of the first surface of the leadframe, a first extension from the first die pad and a second extension from the second die pad;
providing in the laminar sculptured structure of electrically conductive material, at the second surface of the leadframe, a bridge formation coupling the first extension and the second extension, wherein the first extension and the second extension plus the bridge formation therebetween provide a coupling formation of the first die pad and the second die pad;
molding electrically insulating material onto the laminar sculptured structure of electrically conductive material; and
subsequent to said molding, at least partly removing the bridge formation between the first extension and the second extension to decouple the first die pad from the second die pad.

2. The method of claim 1, further comprising mounting semiconductor device components to the first and second die pads at said first surface of the leadframe.

3. The method of claim 1, wherein:
providing the first extension and the second extension comprises forming distal ends of the first and second extension located at a distance from the first and second die pads, respectively; and
providing the bridge formation comprises forming the bridge formation between said distal ends of the first and second extensions with the bridge formation located at a distance from the first and second die pads.

4. The method of claim 1, wherein providing the first extension and the second extension comprises forming the first and second extensions as a finger-like extensions from the first and second die pads, respectively.

5. The method of claim 1, wherein providing the first extension and the second extension comprises forming the first extension and the second extension as mutually converging extensions from the first and second die pads, respectively.

6. The method of claim 1, wherein at least partly removing the bridge formation is performed in conjunction with formation of wettable flanks of the leadframe.

7. The method of claim 1, wherein at least partly removing the bridge formation leaves a cavity at the second surface of the leadframe.

8. A pre-molded leadframe for semiconductor devices, comprising:
a laminar sculptured structure of electrically conductive material comprising opposed first and second surfaces and a plurality of die pads configured to have semiconductor device components mounted thereon;
electrically insulating material molded onto the laminar sculptured structure of electrically conductive material;
wherein:
a first die pad and a second die pad of the plurality of die pads exhibit, at neighboring locations of the first surface of the leadframe, a first extension and a second extension, respectively; and
the second surface of the leadframe has a recessed portion wherein the electrically insulating material is missing, said recessed portion extending bridge-like between said first extension and said second extension.

9. The pre-molded leadframe of claim 8, wherein the plurality of die pads are configured to have semiconductor device components mounted thereon at the first surface of the leadframe.

10. The pre-molded leadframe of claim 8, wherein:
distal ends of the first and second extension are located at a distance from the first and second die pads, respectively; and
said recessed portion is located at a distance from the first and second die pads extending between the distal ends.

11. The pre-molded leadframe of claim 8, wherein the first extension and the second extension each comprise a finger-like extension from the first and second die pads, respectively.

12. The pre-molded leadframe of claim 8, wherein the first extension and the second extension comprise mutually converging extensions from the first and second die pads, respectively.

13. A semiconductor device, comprising:
a pre-molded leadframe including:
a laminar sculptured structure of electrically conductive material comprising opposed first and second surfaces and a plurality of die pads;
electrically insulating material molded onto the laminar sculptured structure of electrically conductive material;
wherein:
a first die pad and a second die pad of the plurality of die pads exhibit, at neighboring locations of the first surface of the leadframe, a first extension and a second extension, respectively; and
the second surface of the leadframe has a recessed portion wherein the electrically insulating material is missing, said recessed portion extending bridge-like between said first extension and said second extension; and
semiconductor device components arranged onto the first and second die pads.

14. The semiconductor device of claim 13, wherein the semiconductor device components are mounted to the first and second die pads at the first surface of the leadframe.

15. The semiconductor device of claim 13, wherein distal ends of the first and second extension are located at a distance from the first and second die pads, respectively.

16. The semiconductor device of claim 15, wherein said recessed portion is located at a distance from the first and second die pads extending between the distal ends.

17. The semiconductor device of claim 13, wherein the first extension and the second extension each comprise a finger-like extension from the first and second die pads, respectively.

18. The semiconductor device of claim 13, wherein the first extension and the second extension comprise mutually converging extensions from the first and second die pads, respectively.
